(19) United States
(12) Patent Application Publication
(10) Pub. No.: US 2025/0086248 A1
(43) Pub. Date: Mar. 13, 2025

(54) METHOD AND APPARATUS WITH SIGNAL DATA RESTORATION

(71) Applicant: SAMSUNG ELECTRONICS CO., LTD., Suwon-si (KR)

(72) Inventor: Junsoo HA, Suwon-si (KR)

(73) Assignee: SAMSUNG ELECTRONICS CO., LTD., Suwon-si (KR)

(21) Appl. No.: 18/827,028

(22) Filed: Sep. 6, 2024

(30) Foreign Application Priority Data
Sep. 8, 2023 (KR) 10-2023-0119981

(51) Int. Cl. G06F 17/14

(52) U.S. Cl. CPC G06F 17/14

(57) ABSTRACT

Disclosed is a method and an apparatus for restoring a damaged signal data including: obtaining a transition matrix by performing a dimensionality reduction analysis with respect to a dataset of an intact signal data within a time series dataset and restoring the damaged signal data in the time series dataset by using the transition matrix.

### CROSS-REFERENCE TO RELATED APPLICATIONS

This application claims priority to and the benefit of Korean Patent Application No. 10-2023-0119981 filed in the Korean Intellectual Property Office on Sep. 8, 2023, the entire contents of which is incorporated herein by reference.

### BACKGROUND

### 1. Field

The present disclosure relates to restoring damaged signal data in a dataset.

### 2. Description of Related Art

Various signals generated in semiconductor manufacture processes may be analyzed to check the status of the manufacture processes. For example, in a plasma process, the spectrum of a gas absorbed from the background may be acquired as a signal for spectroscopic analysis, and analysis such as principal component analysis may be performed using the acquired signal.

In practice, losses such as clipping may occur in signals due to limitations of measuring devices. An undamaged signal may be obtained by adjusting the gain value as needed, but measurement sensitivity with respect to the principal signal may be reduced.

When various analysis techniques are applied to a damaged signal, the damaged signal may be decomposed, for example via Fourier analysis, into a complex combination of small signals rather than a linear combination of the principal signal, and damage to the signal may affect the reliability of the analysis results.

### SUMMARY

This Summary introduces a selection of concepts in a simplified form that are further described below in the Detailed Description. This Summary does not necessarily identify key features or essential features of the claimed subject matter; the claims below speak for themselves as to the range of claimed subject matter.

In one general aspect, a method for restoring a damaged signal data is performed by one or more processors and includes: receiving a time series data set included of an intact signal data sensed at a first time by a sensor and a damaged signal data sensed at a second time by the sensor; obtaining a transition matrix by performing a dimensionality reduction analysis with respect to the intact signal data; and restoring the damaged signal data by using the transition matrix.

The transition matrix may be obtained by performing a principal component analysis as the dimensionality reduction analysis on the intact signal data.

The performing the principal component analysis may be performed through unsupervised learning using a neural network that performs an inference on the intact signal data.

Restoring the damaged signal data by using the transition matrix may include: generating a mask from the damaged signal data; masking the damaged signal data and the transition matrix by using the mask; and restoring the damaged signal data by using a first transpose matrix of the transition matrix, the masked transition matrix, and a second transpose matrix of the masked transition matrix.

The restoring the damaged signal data by using the first transpose matrix of the transition matrix, the masked transition matrix, and the second transpose matrix of the masked transition matrix may include encoding the masked signal data by multiplying the masked transition matrix with the masked signal data.

The restoring the damaged signal data by using the first transpose matrix of the transition matrix, the masked transition matrix, and the second transpose matrix of the masked transition matrix may further include amplifying the encoded signal data by multiplying an inverse matrix of a multiplication of the masked transition matrix and the second transpose matrix of the masked transition matrix by the encoded signal data.

Restoring the damaged signal data by using the first transpose matrix of the transition matrix, the masked transition matrix, and the second transpose matrix of the masked transition matrix may further include: decoding the amplified signal data by multiplying the first transpose matrix of the transition matrix by the amplified signal data.

The method may further include: among units of signal data in the time series dataset, determining some as being units of intact signal data, including the intact signal data, and determining some as being units of damaged signal data, including the damaged signal data.

The units of damaged signal data may be determined to be such based a feature thereof corresponding to a performance limit of a signal sensing device that generated the time series dataset.

Each unit of signal data in the time series dataset may correspond to a spectrum of a signal measured at a corresponding time point, wherein the damaged signal data may correspond to a spectrum of a truncated signal, and wherein the intact signal data may correspond to a spectrum of an untruncated signal.

In another general aspect, a system for analyzing a signal generated by a signal source includes: one or more processors; and memory storing instructions configured to cause the one or more processors to: generate signal data units in a time series dataset of signal data from sensed signals, units of signal data including a unit of damaged data signal and a unit of undamaged signal data; restoring the unit of damaged signal data by using the unit of intact signal data; and analyzing the sensed signals by using the time series dataset including the restored signal data.

The instructions may be further configured to cause the one or more processors to generate a transition matrix for reducing a dimension of the intact signal data through a neural network and restore the damaged signal data by using the transition matrix.

The sensed signals may be provided by a sensor sensing a semiconductor process and the signals may be electromagnetic waves generated by plasma of the semiconductor process.

The sensed signals may be provided by a sensor sensing ultrasonic waves or electromagnetic waves.

The units of signal data may correspond to spectrums of the signals and the damaged unit of signal data may be damaged by physical limitations or performance limitations of a signal sensing device.

In another general aspect, an apparatus for restoring a damaged signal data includes one or more processors; and a memory storing instructions configured to cause the one or more processors to perform a process including: obtaining a transition matrix by performing a dimensionality reduction analysis with respect to a dataset including an intact signal data and a damaged signal data, and restoring the damaged signal data in the time series dataset by using the transition matrix.

The restoring of the damaged signal data in the time series dataset by using the transition matrix may include: generating a mask from the damaged signal data; masking the damaged signal data and the transition matrix by using the mask; and restoring the damaged signal data by using a first transpose matrix of the transition matrix, the masked transition matrix, and a second transpose matrix of the masked transition matrix.

The restoring of the damaged signal data by using the first transpose matrix of the transition matrix, the masked transition matrix, and the second transpose matrix of the masked transition matrix may include: encoding the masked signal data by multiplying the masked transition matrix with the masked signal data; amplifying the encoded signal data by multiplying an inverse matrix of a multiplication of the masked transition matrix and the second transpose matrix of the masked transition matrix with the encoded signal data; and decoding the amplified signal data by multiplying the first transpose matrix of the transition matrix with the amplified signal data.

The process may further include classifying the intact signal data as such, and classifying the damaged signal data as such, based on a performance limit of a signal sensing device having generated the time series dataset, wherein each the undamaged signal data includes a first spectrum of an untruncated signal and the damaged signal data includes a second spectrum of a truncated signal.

The dimensionality reduction analysis may include a principal component analysis (PCA), linear discriminant analysis (LDA), or singular value decomposition (SVD).

Other features and aspects will be apparent from the following detailed description, the drawings, and the claims.

### BRIEF DESCRIPTION OF THE DRAWINGS

FIG. 1 illustrates a signal restoration device according to one or more embodiments.

FIG. 2 illustrates a portion of a signal data of a time series dataset according to one or more embodiments.

FIG. 3 illustrates a signal restoration method according to one or more embodiments.

FIG. 4 illustrates a signal analysis system according to one or more embodiments.

FIG. 5 illustrates a signal analysis method according to one or more embodiments.

FIG. 6 illustrates a neural network according to one or more embodiments.

FIG. 7 illustrates a signal restoration device according to one or more embodiments.

Throughout the drawings and the detailed description, unless otherwise described or provided, the same or like drawing reference numerals will be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

The terminology used herein is for describing various examples only and is not to be used to limit the disclosure. The articles “a,” “an,” and “the” are intended to include the plural forms as well, unless the context clearly indicates otherwise. As used herein, the term “and/or” includes any one and any combination of any two or more of the associated listed items. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof.

Throughout the specification, when a component or element is described as being “connected to,” “coupled to,” or “joined to” another component or element, it may be directly “connected to,” “coupled to,” or “joined to” the other component or element, or there may reasonably be one or more other components or elements intervening therebetween. When a component or element is described as being “directly connected to,” “directly coupled to,” or “directly joined to” another component or element, there can be no other elements intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment, e.g., as to what an example or embodiment may include or implement, means that at least one example or embodiment exists where such a feature is included or implemented, while all examples are not limited thereto.

An Artificial Intelligence (AI) model of the present disclosure is a machine learning model for learning at least one task, which may be implemented as a computer program (instructions) executed by a processor. The task learned by the AI model may be solved through machine learning, or the task may be performed through machine learning. The AI model may be implemented as a computer program (instructions) executed on a computing device, may be downloaded through a network, or may be sold as a product. The AI model may interact with (or be distributed across) a variety of devices through the network.

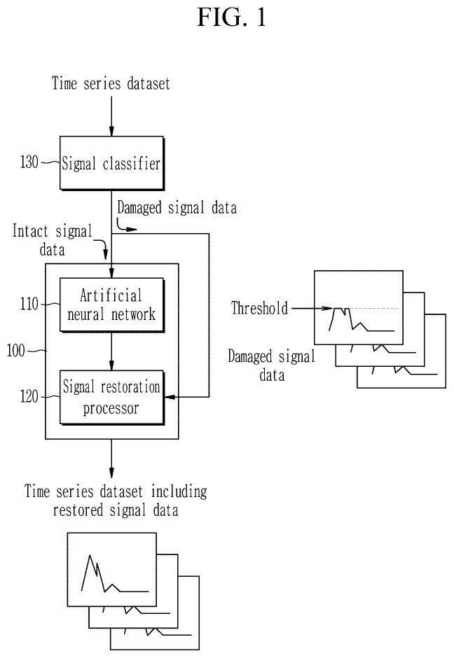

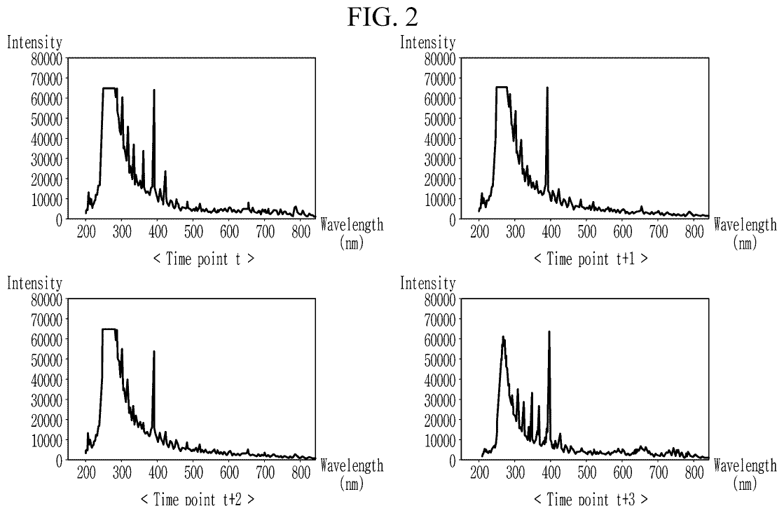

FIG. 1 illustrates a signal restoration device according to one or more embodiments. FIG. 2 illustrates a portion of signal data of a time series dataset according to one or more embodiments. Note that “signal data” is sometimes used herein to refer to discrete units of signal data captured at respective distinct points in time.

Referring to FIG. 1, a signal restoration device 100 include a neural network 110 and a signal restoration processor 120. The signal restoration device 100 may further include, or be in communication with, a signal classifier 130 (or separator) configured to classify (or separate) signal data in the time series dataset into an unclipped signal data (intact signal data) and a clipped signal data (damaged signal data). As shown in FIG. 1, the intact signal data may be passed to the neural network 110, and the damaged signal data may be passed to the signal restoration processor 120.

In some embodiments, the signal restoration device 100 may use the neural network 110 to perform a dimensionality reduction analysis on the intact signal data provided from the signal classifier 130 and thus generate a transition matrix. In addition, the signal restoration processor 120 of the signal restoration device 100 may restore the received damaged signal data included in the same time series dataset (as the intact signa data provided to the neural network 110) by using the transition matrix generated from the intact signal data.

In some embodiments, the time series dataset may include multiple units of signal data collected at respective predetermined time intervals. Each signal data in the time series dataset may be of a same spectrum range (e.g., a wavelength spectrum range or a same frequency spectrum range) of a signal measured at a corresponding time point. That is, the time series data set may include a set of units of discrete time signal data captured at respective times.

The damaged signal data may correspond a spectrum of clipped signal (i.e., signal having truncated peaks) and the intact signal data may correspond a spectrum of unclipped signal (i.e., signal having untruncated peaks). Peak clipping of the signal may be due to sensing limitations of a sensing device measuring the received signal, or limitations of an output device outputting the signal, or an environment in which the signal is transferred.

For example, the time series dataset may be generated by an optical emission spectroscopy (OES or the like) used in the manufacture of a semiconductor (DRAM, FLASH MEMORY, or the like). The OES may generate the time series dataset from a spectrum of gas generated in a semiconductor plasma process (e.g., inductively coupled plasma (ICP)) or the like. These are non-limiting examples.

The signal data generated by the OES may be comprised of a linear combination of background radiation signals and intensity changes that occur when elements in a chamber absorb parts of the spectrum of the plasma. Since the types of reaction elements are generally not diverse in the semiconductor plasma process, the types of principal components according to the results of principal component analysis may not be diverse. In this case, a transition matrix, which may reduce the dimensionality of the intact signal data to a lower dimension, may be calculated, and the damaged signal data may be restored (missing spectrum intensities estimated) by using the transition matrix calculated from the intact signal data.

In some embodiments, a signal data may be represented as a vector in a D-dimensional real number space (R^{D}). For example, when the signal data is generated from plasma in semiconductor process, the signal data may be a vector including D intensity values of D respective wavelengths (or frequencies, as the case may be). At this time, the signal data \vec{X} may be represented as Equation 1 below.

$$\vec{x} = ( {x}_{1} , {x}_{2} , {x}_{3} , … , {x}_{D} ) \qquad Equation 1$$

In Equation 1, x₁ is the value of the first dimension, and x_{D} is the value of the D-th dimension. For example, the signal data representing the spectrum of the plasma may be a signal intensity of each wavelength (or frequency, wave number).

In some embodiments, the signal classifier 130 may determine the damaged signal data in the time series dataset based on a threshold, which might correspond to a performance limit of a signal sensing device, a signal output device, a signal converter, or the like.

The signal classifier 130 may determine a signal data having, for example, an intensity corresponding to a maximum measurable intensity of a signal measuring equipment as the damaged signal data. Alternatively, the signal classifier 130 may determine a signal data having an intensity smaller than the maximum measurable intensity of the signal measuring equipment as the intact signal data.

For example, when the time series dataset is collected by the OES sensing (intensity range: 0 to 65535) having a signal intensity of 16 bits, the signal classifier 130 may determine a signal data having the maximum measurable intensity of the 16-bit OES (i.e., 65535) as the damaged signal data. Alternatively, when a particular signal data is smaller than the maximum measurable intensity of the 16-bit OES, the signal classifier 130 may determine that signal data having the intensity smaller than the maximum measurable intensity as the intact signal data. In some implementations, damaged signal data may be identified by having the maximum signal intensity for a minimum number of bands (and/or consecutive bands), in the frequency domain. It will be appreciated that frequency-domain description herein is readily applicable to time-domain implementation.

For example, when the time series dataset is collected by a microphone or an ultrasonic wave sensor configured to sense a photoacoustic signal generated by a body tissue (skin, organs, or the like) having absorbed electromagnetic or acoustic waves, the signal classifier 130 may determine the damaged signal data based on physical limitations (e.g., size, shape, or the like) and/or measurement limitations (e.g., clipping that occurs when the sound pressure is large) of the microphone or the ultrasonic wave sensor.

Alternatively, the signal classifier 130 may determine a signal data having an intensity corresponding to a maximum output of the signal output device as the damaged signal data, or the signal classifier 130 may determine the signal data having an intensity smaller than the maximum output of the signal output device as the intact signal data.

Alternatively, the signal classifier 130 may determine the damaged signal data in the time series dataset based on a pattern of the signal data. For example, a pattern of the damaged signal data may be one in which equal or substantially equivalent data continues (runs). The equal or substantially equivalent data may continue in a part in which peaks of the signal have been clipped, and at this time, the continuing same data may be largest (maximum intensity) within the signal data. That is, when data of an equal or substantially equivalent size continues or is repeated in the signal data by a predetermined count or more, the signal classifier 130 may determine that signal data as the damaged signal data.

In some embodiments, when the optical of sensing plasma generated in the semiconductor plasma process is strong, signal clipping may occur in the signal sensed by the OES. For example, when the time series dataset includes multiple signal data obtained at 0.1 second intervals, the signal clipping may occur in about 30% of the signal data, statistically.

Referring to FIG. 2, each unit of signal data (i.e., signal) may be a wavelength spectrum representing signal intensities for each represented wavelength (x-axis). The signal classifier 130 may determine/classify the units of signal data of time points t, t+1, and t+2 as damaged, and may determine/classify the signal data of the time point t+3 as intact. In FIG. 2, the signal clipping may occur at the maximum measurable intensity 65535 of the 16-bit OES, as a non-limiting example.

In some embodiments, the signal restoration device 100 may generate the transition matrix by performing the dimensionality reduction analysis (a kind of compression) with respect to an intact signal data (a signal classified as intact) of the time series dataset through the neural network 110, which has been trained by unsupervised learning, for example. The signal restoration device 100 may generate the transition matrix by performing the dimensionality reduction analysis with respect to the intact signal data in the time series dataset and may restore the damaged signal data in the same time series dataset by using the transition matrix generated through the dimensionality reduction analysis performed with respect to the intact signal data.

When N₀ units of intact signal data (each having D dimensions) of the time series dataset are input to the neural network 110, the neural network 110 may output the transition matrix can reduce the dimension of the inputted intact signal data and can maximize capturing of the variance of a dataset. In some embodiments, the transition matrix may reduce the dimensionality of the signal data from D to J (D>J).

The intact unit of signal data may be input to the neural network 110 in the form of N₀×D matrix. Equation 2 below represents a dataset [symbol] ₀, which is a set of the intact signal data \vec{x}₀ input to the neural network 110.

$${𝕏}_{0} = ( \begin{matrix}{\vec{x}}_{0 \_ 1} \\ ⋮ \\ {\vec{x}}_{0 \_ {N}_{0}}\end{matrix} ) = ( \begin{matrix}{\vec{x}}_{0 \_ {1}_{1}} & … & {\vec{x}}_{0 \_ {1}_{D}} \\ ⋮ & ⋱ & ⋮ \\ {\vec{x}}_{0 \_ {N}_{{0}_{1}}} & … & {\vec{x}}_{0 \_ {N}_{{0}_{D}}}\end{matrix} ) \qquad Equation 2$$

In some embodiments, the dimensionality reduction analysis may be performed with a principal component analysis (PCA), a linear discriminant analysis (LDA), a singular value decomposition (SVD), or any other suitable technique. In short, PCA reduces a highly dimensional data (e.g., a spectrum of data) to a lower dimension of data that may be more convenient for analysis. Alternatively, the signal restoration device 100 may perform a nonlinear dimensionality reduction analysis using a technique such as non-negative matrix factorization (NMF), multi-dimensional scaling (MDS), or t-distributed stochastic neighbor embedding (t-SNE) by using the neural network 110.

In some embodiments, the signal restoration device 100 may perform the dimensionality reduction analysis with respect to the dataset [symbol] ₀ of the intact signal data \vec{X}₀ as shown in Equation 3 below through the principal component analysis by using the neural network 110.

$${𝕏}_{0} = A \sum {A}^{T} \qquad Equation 3$$

In Equation 3, A is an orthogonal matrix having eigen vectors of the dataset [symbol] ₀ as column vectors and Σ is a diagonal matrix having eigen values of the dataset [symbol] ₀ as diagonal elements. In some embodiments, A in Equation 3 may be a transition matrix for compressing the dataset to a designated dimension. The transition matrix A may have a dimension of D×J. Here, J represents the size of dimension to be reduced-to in the dimensionality reduction analysis.

In some embodiments, multiplying A by the signal data may serve as a form of encoding of the signal data. Multiplying a transpose matrix A^{T} of A by the signal data may serve as a form of decoding of the signal data. Multiplying Σ by the signal data may serve as a form of amplification processing (or normalization processing) of the signal.

In some embodiments, the signal restoration processor 120 may generate a mask from the damaged signal data to be restored and may mask the damaged signal data and the transition matrix by using the generated mask (details are provided later). The signal restoration processor 120 may individually generate the mask for each of the damaged signal data to be restored and may mask the damaged signal data used to generate the mask. In addition, the signal restoration processor 120 may mask the transition matrix by using the generated mask and may restore the damaged signal data by using a masked transition matrix.

Subsequently, the signal restoration processor 120 may restore the damaged signal data by using the transition matrix and the masked transition matrix. In some embodiments, the signal restoration processor 120 may restore the damaged signal data by performing encoding, amplification, and decoding on the damaged signal data by using a transpose matrix of the transition matrix, the masked transition matrix, and a transpose matrix of the masked transition matrix.

For example, the signal restoration processor 120 may encode the damaged signal data by using the masked transition matrix. The signal restoration processor 120 may amplify the encoded damaged signal data by using an inverse matrix of a multiplication of the masked transition matrix and the transpose matrix of the masked transition matrix. The signal restoration processor 120 may decode the amplified damaged signal data by using the transpose matrix of the transition matrix.

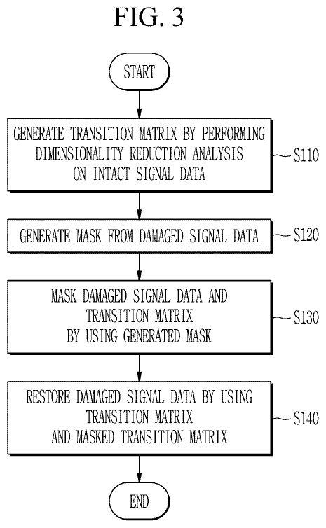

FIG. 3 shows a signal restoration method according to one or more embodiments.

Referring to FIG. 3, at step S110, the signal restoration device 100 may generate the transition matrix by performing the dimensionality reduction analysis on a unit of signal data determined to be intact, and the analysis may be performed through the neural network 110 performing inference on the intact signal data.

In some embodiments, the signal restoration device 100 may perform truncated singular value decomposition (truncated SVD) as the dimensionality reduction analysis. The size J of the singular value in the truncated singular value decomposition may be input to the neural network 110 together with the dataset [symbol] ₀ of the intact signal data as a hyperparameter (TruncatedSVD ( [symbol] ₀, J)).

The signal restoration device 100 may perform the dimensionality reduction analysis with respect to the dataset [symbol] ₀ (N₀≠D) of the intact signal data \vec{x}₀ as shown in Equation 4 (full SVD) below.

$${𝕏}_{0} = U \sum {V}^{T} \qquad Equation 4$$

In Equation 4, U and V are matrices having singular vectors of the dataset [symbol] ₀ as column vectors, and Σ is a diagonal matrix having singular values of the dataset [symbol] ₀ as diagonal elements. U and V may be determined by Equation 5 below.

$${𝕏}_{0} {𝕏}_{0}^{T} = U {\sum }^{2} {U}^{T} {𝕏}_{0}^{T} {𝕏}_{0} = V {\sum }^{2} {V}^{T} \qquad Equation 5$$

In Equation 5, since [symbol] ₀ [symbol] ₀^{T} is a N₀×N₀ matrix, U is a N₀×J matrix. Since [symbol] ₀^{T} [symbol] ₀ is a D×D matrix, V is a D×J matrix. In some embodiments, V, having the D×J dimension, may be used as the transition matrix. Meanwhile, the signal restoration device 100 may use the dimensionality reduction analysis of Equation 3 as a portion of the truncated singular value decomposition process.

Alternatively, in Equation 4, U may be a D×D orthogonal matrix (full SVD), and U′ (D×J dimensions) of the truncated singular value decomposition may be used as the transition matrix.

When the signal data x is multiplied by U, an additional D-dimensional unit of signal data may be generated, having D-dimensional signals aligned in the order of component. When the additional D-dimensional signal data is multiplied by U^{T}, the signal data x may be generated again. At this time, multiplying U by the signal data may be considered as lossless encoding of the signal data, and multiplying U^{T} by the signal data may be considered as lossless decoding of the signal data. Since U is a definite matrix (orthogonal matrix), U⁻¹=U^{T}.

At step S120, the signal restoration processor 120 of the signal restoration device 100 may generate a mask from the clipped signal data \vec{x}_{c}, to be restored. In some embodiments, the signal restoration processor 120 may generate a mask for masking the damaged part of the clipped signal data based on a performance limit of the signal measuring equipment and/or the signal output device (e.g., a clipping magnitude or an intensity threshold). The signal restoration processor 120 may determine the data in the signal data corresponding to performance limit of the signal measuring equipment and/or the signal output device as the damaged part, and may generate a mask for deleting the damaged part from the signal data. That is, the signal restoration processor 120 may delete the damaged part in the clipped signal data by performing masking processing on the clipped signal data by using the mask. When the unit of signal data is D dimensional, the masked signal data \vec{x}′_{c} (may be D′ dimension (D′<D). Equation 6 below represents the masked clipped signal data \vec{x}′_{c}.

$${\vec{x}}_{c}^{′} = ( {x}_{1} , {x}_{2} , {x}_{p} {X}_{p + 1} , … , {X}_{s} , {X}_{w} , {X}_{w + 1} , … , {x}_{{D}^{′}} ) \qquad Equation 6$$

In Equation 6, p is an arbitrary natural number that is larger than 3, and p, s, and w are natural numbers, which are not continuous. Therefore, in the signal data \vec{x}_{c}, since some component between x₂ and xₚ has been deleted by masking and also the component between xₛ and x_{w} is deleted by masking, the masked signal data \vec{x}′_{c} may be generated.

In some embodiments, at step S130, the signal restoration processor 120 may perform masking with respect to the clipped signal data \vec{x}_{c} and the transition matrix A by using the mask. Since the signal restoration processor 120 performs masking with respect to the clipped signal data \vec{x}_{c} and the transition matrix A by using the mask, only signal components that are not clipped may be estimated from the masked signal data \vec{x}′_{c} by encoding by the masked transition matrix A′.

The masked transition matrix A′ does not include components corresponding to the damaged part of the subject unit of signal data among principal components of the transition matrix A. Therefore, when encoding is performed on the masked signal data \vec{x}′_{c} (by multiplying the masked transition matrix A′, components corresponding to the damaged part of the signal data may not be estimated. The masked signal data \vec{x}′_{c} (may have D′ dimension and the dimension of the masked transition matrix A′ may be D′×J.

In some embodiments, at step S140, the signal restoration processor 120 may generate a restored signal data \vec{x}_{rec} by restoring the clipped signal data \vec{x}_{c} by using the transition matrix and the masked transition matrix. The signal restoration processor 120 may generate the restored signal data \vec{x}_{rec} as shown in Equation 7 below.

$${\vec{x}}_{r e c} = {\vec{x}}_{c}^{′} \cdot {{A}^{′} ( {( {A}^{′} )}^{T} {A}^{′} )}^{- 1} {A}^{T} \qquad Equation 7$$

In Equation 7, a multiplication of the masked signal data \vec{x}′_{c} and the masked transition matrix A′ may be encoding the masked signal data \vec{x}′_{c} by using the masked transition matrix A′. Because the signal restoration processor 120 multiplies the masked transition matrix A′ by the masked signal data \vec{x}′_{c}, the signal data may be under-estimated. At this time, the degree of under-estimation may be represented as a multiplication of the masked transition matrix A′ and a transpose matrix (A′)^{T} of the masked transition matrix.

In some embodiments, when the part (the damaged part) deleted by the masking is not excessively large, the masked transition matrix A′ may be a roughly orthogonal matrix. Therefore, the possibility of numerical error may be relatively low when performing encoding by multiplying the masked transition matrix A′ by the masked signal data \vec{x}′_{c}.

In Equation 7, multiplying the inverse matrix of the multiplication of the masked transition matrix A′ and the transpose matrix (A′)^{T} of the masked transition matrix may amplify (or normalize) the encoded signal data. The signal restoration processor 120 may amplify the signal data under-estimated through the multiplication of the masked signal data \vec{x}′_{c} and the masked transition matrix A′ by using the inverse matrix of the multiplication of the masked transition matrix A′ and the transpose matrix (A′)^{T} of the masked transition matrix. Since the masked transition matrix A′ is a symmetric matrix, the signal restoration processor 120 may estimate values close to original component of the damaged part by multiplying the inverse matrix of multiplication of the masked transition matrix and the transpose matrix of the masked transition matrix to the encoded signal data.

Each column of the masked transition matrix A′ generated by deletion of a particular row of the transition matrix A may become non-orthogonal. Accordingly, when the signal data is encoded by multiplying the masked transition matrix A′ to the masked signal data and only A^{T} is multiplied to the encoded signal, the signal may become attenuated compared to the case that A and A^{T} are multiplied to the signal data that is not masked. Therefore, multiplying the inverse matrix of the multiplication of A′ and (A′)^{T} may cause amplification with respect to the above attenuation.

Thereafter, the signal restoration processor 120 may generate the restored signal data of the damaged signal data by decoding the amplified signal data, which may be done by multiplying the transpose matrix A^{T} of the transition matrix with the amplified signal data.

Table 1 below shows pseudo-code for implementing the signal restoration method described above.

TABLE 1
Requires: Signal data under same physical experiments that contains both
clipped and unclipped signals
At least one spectrum (dimension) is not affected by clipping.
Input: Unclipped OES Signal Data X0 in R\hat{ }(N0 times D) and clipped OES
Signal x in R\hat{ }D, where N0 is the numbers of observations, D is the
dimension of the signal, Clipping threshold T, PCA Dimension J
Output: Recovered OES Signal Data x_rec in R\hat{ }D
1: Apply ‘TruncatedSVD(X0, J)‘ to get the transition matrix A in R\hat{ }(D
times J)
2: For x in R\hat{ }D, create a mask ‘mask = (i : x[i] <= T)‘
3: x_rec := x[mask] A[mask, :] (A[mask, :]\hat{ }T A[mask, :])\hat{ }−1 A\hat{ }T

When a time series dataset is damaged due to physical (e.g., sensor) or logical (e.g., calculation) limitations, the damaged signal data may be successfully restored by using a transition matrix generated based on, undamaged intact signal data in the time series dataset. Additionally, since the damaged portion within the time series dataset is restored, the accuracy of signal analysis on the time series dataset may be improved by using the restored time series dataset.

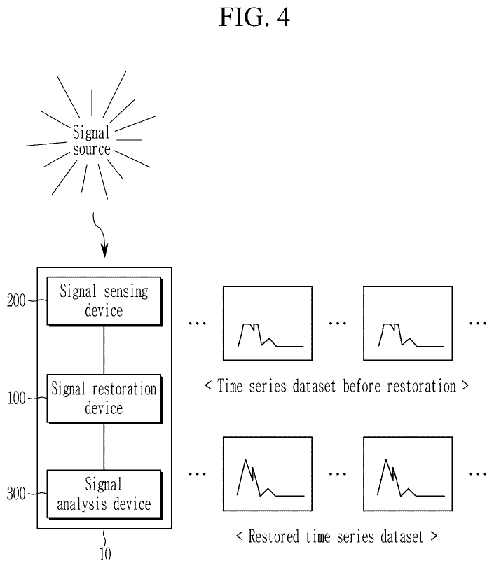

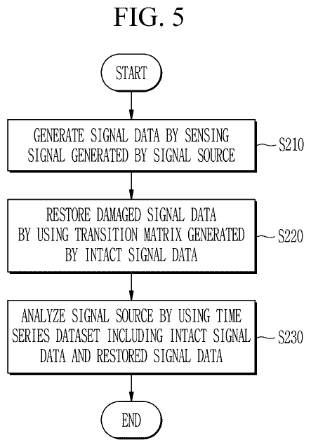

FIG. 4 shows a signal analysis system according to one or more embodiments. FIG. 5 shows a signal analysis method according to one or more embodiments.

Referring to FIG. 4, a signal analysis system 10 according to some embodiments may include a signal sensing device 200, the signal restoration device 100, and a signal analysis device 300.

When the time series dataset received from the signal sensing device 200 includes damaged signal data, the signal restoration device 100 may generate the transition matrix based on intact (undamaged) signal data in the time series dataset and restore the damaged signal data by using the transition matrix generated from the intact signal data to estimate the missing (e.g., clipped) parts of the damaged signal data. Thereafter, the signal restoration device 100 may transmit the time series dataset including both the intact signal data and the restored signal data to the signal analysis device 300, and the signal analysis device 300 may perform analysis with respect to a signal source by using the restored time series dataset.

Referring to FIG. 5, at step S210, the signal sensing device 200 may generate the signal data by sensing a signal generated by the signal source. The signal source may generate a signal in the form of a wave (e.g., electromagnetic energy, acoustic energy, etc.), and the signal sensing device 200 may generate the spectrum of the wave as the signal data by sensing the wave at predetermined time intervals. A set of signal data sensed during a predetermined time period may constitute one time series dataset.

In some embodiments, a signal generated by the signal source may be an electromagnetic wave generated in a semiconductor plasma process, and the signal sensing device 200 may be the optical emission spectroscopy (OES). Alternatively, the signal generated by the signal source is a sound wave or ultrasonic wave, and the signal sensing device 200 may be a microphone or the ultrasonic wave sensor. For example, the signal may be a photoacoustic signal generated by reflection of ultrasonic waves by the body tissue (skin, organs, or the like), and the signal sensing device may be the ultrasonic wave sensor configured to obtain a photoacoustic signal. Due to physical limitations or performance limitations of the signal sensing device of the optical emission spectroscopy, microphone, and the ultrasonic wave sensor, or the like, damage (e.g., signal clipping) may occur in the signal data that represent the spectrum of the signal from the signal source.

Referring to FIG. 5, at step S220, the signal restoration device 100 may restore the damaged signal data in the time series dataset by using the intact signal data in the time series dataset generated by the signal sensing device. The signal restoration device 100 may receive the intact signal data and the damaged signal data from the signal classifier 130.

The signal restoration device 100 may generate the transition matrix configured to reduce the dimensionality of dataset of the intact signal data by performing the unsupervised learning (e.g., the dimensionality reduction analysis) by using the neural network 110. Subsequently, the signal restoration device 100 may restore the damaged signal data by using the transition matrix generated from the dataset of the intact signal data. The (i) intact signal data (that is an object of the dimensionality reduction analysis) and the (ii) damaged signal data (restored by the transition matrix generated through the dimensionality reduction analysis) may both be included in the same time series dataset.

When the damaged signal data is restored, the signal restoration device 100 may transmit the restored time series dataset including the intact signal data and restored signal data to the signal analysis device 300. Subsequently, at step S230, the signal analysis device 300 may analyze signals of the signal source based on the restored time series dataset.

In some embodiments, since the signal data damaged by signal clipping or the like is restored in the restored time series dataset, integrity of the time series dataset provided to the signal analysis device 300 may be improved. Therefore, the signal analysis device 300 may accurately perform a preliminary work (e.g., the dimensionality reduction analysis such as PCA) that precedes full-scale analysis of the time series dataset based on the restored time series dataset, and thereby, the accuracy of subsequent signal analysis using the time series dataset may be improved. For example, the signal analysis device 300 may perform a critical dimension (CD) prediction task at a high performance (e.g., R2 score of 0.8) by using the restored time series dataset.

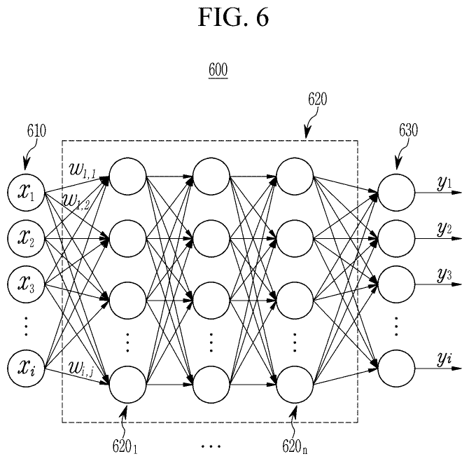

FIG. 6 shows a neural network according to one or more embodiments.

Referring to FIG. 6, a neural network according to some embodiments 600 may include an input layer 610 and an output layer 630, and may further include a hidden layer 620. The input layer 610, the hidden layer 620, and the output layer 630 may each include a respective set of nodes, and strengths of connections between the nodes may be represented by weights (i.e., a weight connection). The nodes included in the input layer 610, the hidden layer 620, and the output layer 630 may be fully connected to each other. In some embodiments, the number of parameters (weights and biases) may be equal to the number of the connections in the neural network 600. Architectures other than fully connected networks may be used.

The input layer 610 may include input nodes (x₁ to xᵢ), and the number of the input nodes (x₁ to xᵢ) may correspond to the number of independent variables. In the case of unsupervised according to some embodiments, when the signal restoration device 100 inputs the intact signal data the time series dataset to the input layer 610 of the neural network 600, the output layer 630 of the neural network 600 may output the transition matrix based on the intact signal dataset.

The hidden layer 620 may be positioned between the input layer 610 and the output layer 630, and may include at least one hidden layer (620₁ to 620ₙ). The output layer 630 may include at least one output node (y₁ to yⱼ). An activation function may be used to the hidden layer 620 and the output layer 630. In some embodiments, the neural network 600 may be learned by adjusting the weight of the hidden node included by the hidden layer 620.

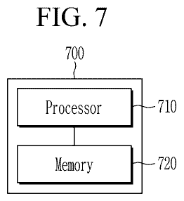

FIG. 7 shows a signal restoration device according to one or more embodiments.

The signal restoration device may be realized into a computer system, for example, a computer readable medium (not a signal per se). Referring to FIG. 7, the computer system 700 includes a processor 710 and a memory 720 (“processor” refers to one or more processors). The memory 720 may be connected to the processor 710 and may store various types of information for driving the processor 710 or at least one program executed by the processor 710. In addition, the memory 720 may store instructions configured to cause the processor 710 perform a process including steps or methods described above.

The processor 710 may realize functions, stages, steps, or methods proposed in the embodiment. An operation of the computer system 700 may be realized by the processor 710. In some embodiments, the processor 710 may include a central processing unit (CPU), a graphics processing unit (GPU), a neural processing unit (NPU), and/or the like. For example, the CPU may execute a program stored in the memory 720, and may transmit commands and/or instructions required for execution of the above-described signal restoration method and/or signal analysis method to respective components. The GPU and/or the NPU may be used to perform a matrix operation included in signal restoration method described above. When the matrix operation is processed by using the GPU and/or the NPU, the signal may be rapidly restored.

The memory 720 may be provided inside/outside the processor, and may be connected to the processor through various means known to a person skilled in the art. The memory represents a volatile or non-volatile storage medium in various forms, and for example, the memory may include a read-only memory (ROM) and a random-access memory (RAM).

The computing apparatuses, the sensors, the electronic devices, the processors, the memories, the displays, the information output system and hardware, the storage devices, and other apparatuses, devices, units, modules, and components described herein with respect to FIGS. 1-7 are implemented by or representative of hardware components. Examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. A hardware component may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 1-7 that perform the operations described in this application are performed by computing hardware, for example, by one or more processors or computers, implemented as described above implementing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media. Examples of a non-transitory computer-readable storage medium include read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as multimedia card micro or a card (for example, secure digital (SD) or extreme digital (XD)), magnetic tapes, floppy disks, magneto-optical data storage devices, optical data storage devices, hard disks, solid-state disks, and any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above disclosure, the scope of the disclosure may also be defined by the claims and their equivalents, and all variations within the scope of the claims and their equivalents are to be construed as being included in the disclosure.

What is claimed is:

1. A method for restoring a damaged signal data, the method performed by one or more processors and comprising:
receiving a time series data set comprised of an intact signal data sensed at a first time by a sensor and a damaged signal data sensed at a second time by the sensor;
obtaining a transition matrix by performing a dimensionality reduction analysis with respect to the intact signal data; and
restoring the damaged signal data by using the transition matrix.

2. The method of claim 1, wherein the transition matrix is obtained by performing a principal component analysis as the dimensionality reduction analysis on the intact signal data.

3. The method of claim 2, wherein the performing the principal component analysis is performed through unsupervised learning using a neural network that performs an inference on the intact signal data.

4. The method of claim 1, wherein restoring the damaged signal data by using the transition matrix comprises:
generating a mask from the damaged signal data;
masking the damaged signal data and the transition matrix by using the mask; and
restoring the damaged signal data by using a first transpose matrix of the transition matrix, the masked transition matrix, and a second transpose matrix of the masked transition matrix.

5. The method of claim 4, wherein the restoring the damaged signal data by using the first transpose matrix of the transition matrix, the masked transition matrix, and the second transpose matrix of the masked transition matrix comprises
encoding the masked signal data by multiplying the masked transition matrix with the masked signal data.

6. The method of claim 5, wherein the restoring the damaged signal data by using the first transpose matrix of the transition matrix, the masked transition matrix, and the second transpose matrix of the masked transition matrix further comprises
amplifying the encoded signal data by multiplying an inverse matrix of a multiplication of the masked transition matrix and the second transpose matrix of the masked transition matrix by the encoded signal data.

7. The method of claim 6, wherein restoring the damaged signal data by using the first transpose matrix of the transition matrix, the masked transition matrix, and the second transpose matrix of the masked transition matrix further comprises:
decoding the amplified signal data by multiplying the first transpose matrix of the transition matrix by the amplified signal data.

8. The method of claim 1, further comprising:
among units of signal data in the time series dataset,
determining some as being units of intact signal data, including the intact signal data, and
determining some as being units of damaged signal data, including the damaged signal data.

9. The method of claim 8, wherein the units of damaged signal data are determined to be such based on a feature thereof corresponding to a performance limit of a signal sensing device, including the sensor, that generated the time series dataset.

10. The method of claim 6, wherein each unit of signal data in the time series dataset corresponds to a spectrum of a signal measured at a corresponding time point, wherein the damaged signal data corresponds to a spectrum of a truncated signal, and wherein the intact signal data corresponds to a spectrum of an untruncated signal.

11. A system for analyzing a signal generated by a signal source, the system comprising:
one or more processors; and
memory storing instructions configured to cause the one or more processors to:
generate signal data units in a time series dataset of signal data from sensed signals, units of signal data including a unit of damaged data signal and a unit of undamaged signal data;
restoring the unit of damaged signal data by using the unit of intact signal data; and
analyzing the sensed signals by using the time series dataset including the restored signal data.

12. The system of claim 11, wherein the instructions are further configured to cause the one or more processors to generate a transition matrix for reducing a dimension of the intact signal data through a neural network and restore the damaged signal data by using the transition matrix.

13. The system of claim 11, wherein the sensed signals are provided by a sensor sensing a semiconductor process and the signals are electromagnetic waves generated by plasma of the semiconductor process.

14. The system of claim 11, wherein the sensed signals are provided by a sensor sensing ultrasonic waves or electromagnetic waves.

15. The system of claim 11, wherein the units of signal data corresponds to spectrums of the signals and the damaged unit of signal data is damaged by physical limitations or performance limitations of a signal sensing device.

16. An apparatus for restoring a damaged signal data, the apparatus comprising one or more processors; and
a memory storing instructions configured to cause the one or more processors to perform a process comprising:
obtaining a transition matrix by performing a dimensionality reduction analysis with respect to a dataset comprising an intact signal data and a damaged signal data, and
restoring the damaged signal data in the time series dataset by using the transition matrix.

17. The apparatus of claim 16, wherein the restoring of the damaged signal data in the time series dataset by using the transition matrix comprises:
generating a mask from the damaged signal data;
masking the damaged signal data and the transition matrix by using the mask; and
restoring the damaged signal data by using a first transpose matrix of the transition matrix, the masked transition matrix, and a second transpose matrix of the masked transition matrix.

18. The apparatus of claim 17, wherein
the restoring of the damaged signal data by using the first transpose matrix of the transition matrix, the masked transition matrix, and the second transpose matrix of the masked transition matrix comprises:
encoding the masked signal data by multiplying the masked transition matrix with the masked signal data;
amplifying the encoded signal data by multiplying an inverse matrix of a multiplication of the masked transition matrix and the second transpose matrix of the masked transition matrix with the encoded signal data; and
decoding the amplified signal data by multiplying the first transpose matrix of the transition matrix with the amplified signal data.

19. The apparatus of claim 16, wherein the process further comprises
classifying the intact signal data as such, and classifying the damaged signal data as such, based on a performance limit of a signal sensing device having generated the time series dataset,
wherein each the undamaged signal data comprises a first spectrum of an untruncated signal and the damaged signal data comprises a second spectrum of a truncated signal.

20. The apparatus of claim 16, wherein the dimensionality reduction analysis includes a principal component analysis (PCA), linear discriminant analysis (LDA), or singular value decomposition (SVD).
